(19) United States
(12) Patent Application Publication
(10) Pub. No.: US 2007/0210418 A1
(43) Pub. Date: Sep. 13, 2007

(54) SEMICONDUCTOR MEMORY DEVICE

(75) Inventor: Hiroomi NAKAJIMA, Yokohama-Shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/680,931

(22) Filed: Mar. 1, 2007

(30) Foreign Application Priority Data
Mar. 9, 2006 (JP) 2006-064338

(51) Int. Cl. H01L 29/00

(52) U.S. Cl. 257/547

(57) ABSTRACT

A memory includes a semiconductor layer provided on an insulation film provided on a first conductivity type substrate; a first well of a second conductivity type provided in the substrate; second wells of the first conductivity type provided in the first well; a third well of a second conductivity type provided in the substrate; a memory cell including a first source, a first drain and a body region, the first source and drain being formed in the semiconductor layer located above one of the second wells; a first logic circuit including a second source, a second drain and a channel region, the second source and drain being formed on the semiconductor layer above another one of the second wells; and a second logic circuit including a third source, a third drain and a channel region, the third source and drain being formed on the semiconductor layer above the third well.

### CROSS-REFERENCE TO RELATED APPLICATION

This application is based upon and claims the benefit of priority from the prior Japanese Patent Applications No. 2006-64338, filed on Mar. 9, 2006, the entire contents of which are incorporated herein by reference.

### BACKGROUND OF THE INVENTION

1. Field of the Invention

The present invention relates to a semiconductor memory device.

2. Related Art

In recent years, an FBC (floating-body-cell) memory device is expected as a memory device to replace a DRAM device. In the FBC memory device, an FET (field effect transistor) including a floating body (hereinafter, also “body region”) is formed on an SOI (silicon-on-insulator) substrate, and the FET stores therein data “1” or data “0” according to the number of carries accumulated in the body region.

A silicon-on-insulator layer and a BOX (buried oxide) layer on the SOI substrate have been made much thinner in recent years, and the thicknesses of the SOI layer and the BOX layer have been reduced to about 50 nm or less.

If the thickness of the BOX layer is reduced to 50 nm or less, impurities in the body region or a channel region are possibly diffused into a support substrate through the BOX layer. Due to this, if a memory cell and a logic circuit element are N-type FETs, a P-type well is normally provided below the BOX layer. If the memory cell and the logic circuit element are P-type FETs, an N-type well is normally provided below the BOX layer.

Furthermore, if the support substrate of the SOI substrate consists of, for example, a P-type semiconductor, a P-type well and a P-type support substrate are provided below the N-type FET through the BOX layer. In this case, since semiconductors below the N-type FET are all P-type semiconductors, the reduced-thickness BOX layer is often subjected to electrostatic breakdown due to plasma damage or the like. Conversely, if the support substrate of the SOI substrate consists of an N-type semiconductor, semiconductors below the P-type FET are all N-type semiconductors. Due to this, the BOX layer is similarly often subjected to the electrostatic breakdown.

### SUMMARY OF THE INVENTION

A semiconductor memory device according to an embodiment of the present invention comprises a support substrate including a first conductivity type semiconductor; an insulation film provided on the support substrate; a semiconductor layer provided on the insulation film; a first well of a second conductivity type provided in the support substrate; second wells of the first conductivity type provided in the first well; a third well of a second conductivity type provided in the support substrate; a memory cell including a first source of the second conductivity type, a first drain of the second conductivity type and a body region formed between the first source and the first drain, the first source and the first drain being formed in the semiconductor layer located above one of the second wells, the body region being in an electrically floating state and accumulating or emitting charges for storing therein data; a first logic circuit element including a second source of the second conductivity type, a second drain of the second conductivity type and a channel region of the first conductivity type formed between the second source and the second drain, the second source and the second drain being formed on the semiconductor layer above another one of the second wells; and a second logic circuit element including a third source of the first conductivity type, a third drain of the first conductivity type and a channel region of the second conductivity type formed between the third source and the third drain, the third source and the third drain being formed on the semiconductor layer above the third well.

A method of manufacturing a semiconductor memory device according to an embodiment of the present invention comprises preparing a semiconductor substrate including a support substrate including a first conductivity type semiconductor, an insulation film provided on the support substrate, and a semiconductor layer provided on the insulation film; forming a first well of a second conductivity type in the support substrate; forming second wells of the first conductivity type in the first well; forming a third well of the first conductivity type in the support substrate; and forming a first source of the second conductivity type and a first drain of the second conductivity type in the semiconductor layer above one of the second well, a second source of the second conductivity type and a second drain of the second conductivity type in the semiconductor layer above another one of the second well, and a third source of the first conductivity type and a third drain of the first conductivity type in the semiconductor layer above the third well, wherein

the semiconductor layer between the first source and the first drain is used as a body region of the first conductivity type which is in an electrically floating state and accumulates or emits charges for storing therein data, the semiconductor layer between the second source and the second drain is used as a channel region of the first conductivity type, and the semiconductor layer between the third source and the third drain is used as a channel region of the second conductivity type.

### BRIEF DESCRIPTION OF THE DRAWINGS

FIG. 1 is a cross-sectional view of an FBC memory device according to an embodiment of the present invention;

FIG. 2 is a cross-sectional view showing a manufacturing method of an FBC memory device according to an embodiment of the present invention;

FIG. 3 is a cross-sectional view showing a manufacturing method of an FBC memory device following FIG. 2;

FIG. 4 is a cross-sectional view showing a manufacturing method of an FBC memory device following FIG. 3;

FIG. 5 is a cross-sectional view showing a manufacturing method of an FBC memory device following FIG. 4; and

FIG. 6 is a cross-sectional view showing a manufacturing method of an FBC memory device following FIG. 5.

### DETAILED DESCRIPTION OF THE INVENTION

Hereafter, embodiments of the present invention will be described with reference to the drawings. Note that the invention is not limited to the embodiments. In the following embodiments, it is assumed that a first conductivity type of the semiconductor is a P-type and that a second conductivity type of the semiconductor is an N-type. However, even if the first conductivity type and the second conductivity type are N-type and P-type, respectively, the effects of the present invention are the same.

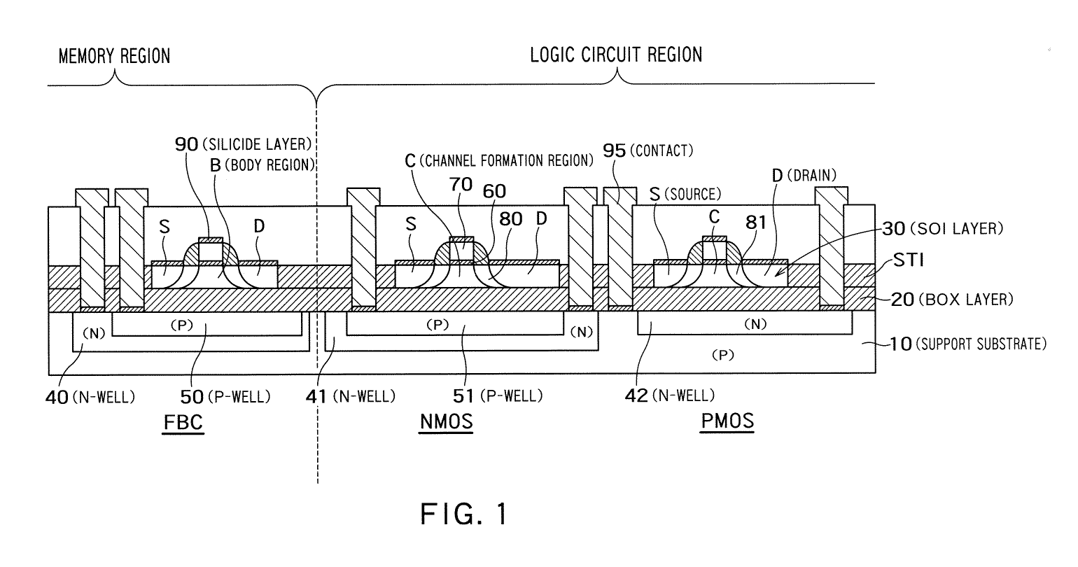

FIG. 1 is a cross-sectional view of an FBC memory device according to an embodiment of the present invention. The FBC memory device is a memory-logic integrated semiconductor memory device including memory cells and logic circuit elements formed on the same substrate. The FBC memory device is formed on an SOI substrate including a support substrate 10, a BOX layer 20, and an SOI layer 30.

The support substrate 10 consists of, for example, P-type silicon having an impurity concentration of 10¹⁴ cm⁻³. The BOX layer 20, which is provided on the support substrate 10, consists of, for example, a silicon oxide film. A thickness of the BOX layer 20 is, for example, equal to or smaller than 50 nm. It is preferable that the thickness of the BOX layer 20 is smaller so as to increase a signal difference (threshold voltage difference) between data “1” and data “0” stored in memory cells and to stabilize operations. The SOI layer 30, which is provided on the BOX layer 20, consists of, for example, silicon single crystal.

A memory region includes memory cells (FBC) each made of an N-type FET. While FIG. 1 is a cross-section of one FBC, a memory cell array (not shown) is constituted by arranging a plurality of FBCs two-dimensionally.

In the memory region, an N-type deep well 40 (hereinafter, “N-well 40”) is formed, as a first well, in the support substrate 10. The N-well 40 contains phosphorus having an impurity concentration of, for example, 7×10¹⁷ cm⁻³. A P-type well 50 (hereinafter, “P-well 50”) is formed, as a second well, in the N-well 40. The P-well 50 contains boron having an impurity concentration of, for example, 1×10¹⁸ cm⁻³. The FBC is provided in the SOI layer 30 above the second well 50. The P-well 50 is formed to have the same conductivity type as that of a body region B and that of a channel formation region C to stabilize an impurity concentration of the body region B and that of the channel formation region C.

In the memory region, an N-type source S and an N-type drain D are formed in the SOI layer 30. Furthermore, the P-type body region B is formed between the source S and the drain D. The body region B is surrounded by the source S, the drain D, the BOX layer 20, a gate insulation film 60, and an STI (shallow trench isolation) region, and is in an electrically floating state. The FBC accumulates or emits charges in or from the body region B for storing therein the data “0” or the data “1”, and stores the data “1” or the data “0” according to the number of carriers accumulated in the body region B.

The gate insulation film 60 is formed on the body region B. The gate insulation film 60 can consist of, for example, a silicon oxide film, a silicon nitride film, a silicon oxynitride film or a high dielectric material such as hafnium silicate. A gate electrode 70 is provided on the gate insulation film 60. The gate electrode 70 can consist of, for example, polysilicon or silicide.

In a normal operation, the P-well 40 is set to have a constant potential (e.g., ground potential) so as to stabilize operations of the FBC and logic circuit elements. Furthermore, the N-well 50 can be used as a gate for back bias. It is thereby possible to enhance a data retention ability and a data writing ability of the FBC.

The STI is formed, as an element isolation region, between the memory region and the logic circuit region. By providing the STI, the FBC is electrically isolated from the logic circuit elements.

In the logic circuit region, an N-type deep well 41 (hereinafter, “N-well 41”) is formed, as a first well, in the support substrate 10 in a region for forming an N-type FET as a first logic circuit element. An impurity concentration of the N-well 41 can be set equal to that of the N-well 40. Furthermore, a P-type well 51 (hereinafter, “P-well 51”) is formed, as a second well, in the N-well 41. An impurity concentration of the P-well 51 can be set equal to that of the P-well 50. The N-type FET is provided in the SOI layer 30 present above the P-well 51.

The N-type FET includes an N-type source S and an N-type drain D formed on the SOI layer 30, and a P-type channel formation region C formed between the source S and the drain D.

The gate insulation film 60 is formed on the channel formation region C, and the gate electrode 70 is provided on the gate insulation film 60.

In the logic circuit region, an N-type deep well 42 (hereinafter, “N-well 42”) is formed, as a second well, in the support substrate 10 in a region for forming a P-type FET as a second logic circuit element. An impurity concentration of the N-well 42 can be set equal to that of the N-well 40. The P-type FET is provided in the SOI layer 30 present above the N-well 42. It is to be noted that a P-well is not formed in the region for forming the P-type FET. This is because a pn junction is already formed between the N-well 42 and the P-type support substrate 10.

The P-type FET includes a P-type source S and a P-type drain D formed on the SOI layer 30, and an N-type channel formation region C formed between the source S and the drain D.

The gate insulation film 60 is formed on the channel formation region C, and the gate electrode 70 is provided on the gate insulation film 60. A silicide layer 90 is formed on contact regions of the source S, the drain D, the gate electrode 70, the wells 40, 41, 42, 50, and 51.

Although FIG. 1 shows one N-type FET and one P-type FET, many N-type FET and P-type FET actually constitute the logic circuit region.

In the embodiment, the P-well 50 is provided below the P-type body region B of the FBC, and the N-well 40 is provided around the P-well 50. Due to this, the N-well 40 interposes between the P-well 50 and the P-type support substrate 10, and a pn junction is formed between the N-well 40 and the support substrate 10. If a potential in an opposite direction is applied to the pn junction, a depletion layer extends. Therefore, a breakdown voltage of the pn junction relaxes an electric field applied to the BOX layer 20. Accordingly, a higher potential can be applied to the source S, the drain D, the body region B or the gate electrode 70 than that applied for the conventional FBC memory device.

If the BOX layer 20 has a thickness of, for example, 50 nm, a breakdown voltage of the BOX layer 20 is about 50 V. If the impurity concentration of the N-well 40 is 7×10¹⁸ cm⁻³ and that of the P-well 50 is 1×10¹⁸ cm⁻³, the breakdown voltage of the pn junction between the wells 40 and 50 is about 8 V. Namely, the breakdown voltage of the BOX layer in the conventional FBC memory device is 50 V whereas the breakdown voltage of the BOX layer 20 in the FBC memory device according to the embodiment is apparently 58 V. In other words, it is possible to reduce plasma damage inflicted on the FBC memory device according to the embodiment during manufacturing steps by about 15% with respect to the plasma damage inflicted on the conventional FBC memory device.

If the BOX layer 20 has a thickness of 25 nm, the breakdown voltage of the BOX layer 20 is about 25 V. Therefore, according to the present embodiment, the plasma damage on the FBC memory device during the manufacturing steps can be reduced by about 30% with respect to the plasma damage on the conventional FBC memory device.

In this manner, according to the embodiment, by distributing the electric field applied to the BOX layer 20 to the pn junction formed in the support substrate 10, electrostatic breakdown caused by ESD (electrostatic discharge) can be suppressed.

Moreover, the presence of the wells 40 and 41 enables the wells 50 and 51 to be electrically isolated from the support substrate 10. It is thereby possible to set potentials of the wells 50, 51, and 42 independently of one another. Due to this, the wells 40 and 41 are connected to a voltage source different from that of the wells 50 and 51 and the support substrate 10.

Furthermore, since the impurity concentration of the support substrate 10 is low or equal to or lower than 10¹⁵ cm⁻³, the breakdown voltage of the pn junction present below the P-type FET is higher than that of the pn junction present below the FBC or the N-type FET. In the embodiment, since the junction breakdown voltage is equal to or higher than 100 V, it is possible to almost suppress the electrostatic breakdown during the manufacturing steps.

A method of manufacturing the FBC memory device according to the embodiment will be explained.

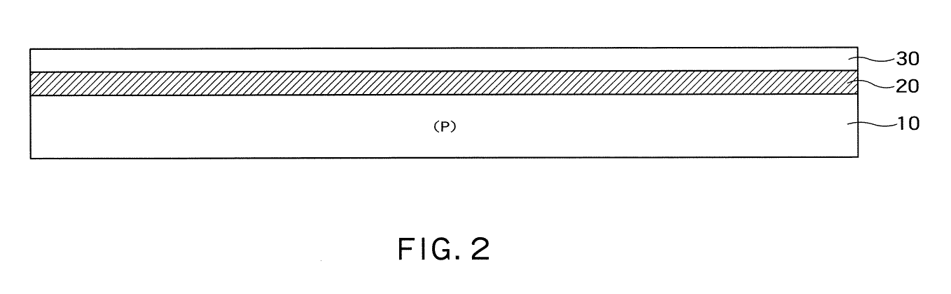

As shown in FIG. 2, the SOI substrate is prepared. The support substrate 10 can consist of a P-type semiconductor having a relatively low impurity concentration (10¹⁴ cm⁻³). The thickness of the BOX layer 20 is equal to or smaller than 50 nm.

A trench is formed by removing the SOI layer 30 in the element isolation region. By filling the trench with an insulation film, the STI region is formed.

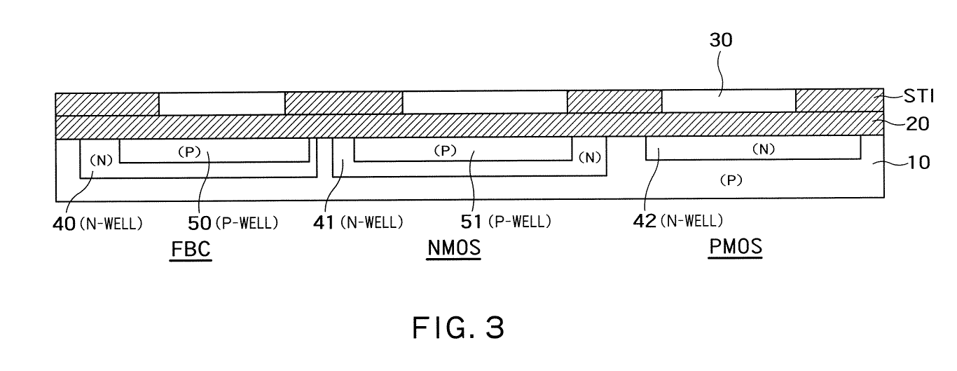

As shown in FIG. 3, the N-wells 40 and 41 are formed in the region for forming the FBC and that for forming the N-type FET. At this moment, phosphorus ions at a dosage of, for example, about 3×10¹³ cm⁻² are implanted into the support substrate 10 at energy of about 1500 keV, thereby forming the N-wells 40 and 41. The N-wells 40 and 41 can be formed simultaneously at the same step to decrease the number of manufacturing steps or formed at different steps to make the N-wells 40 and 41 different in impurity concentration and depth.

Next, boron ions at a dosage of about 8×10¹³ cm⁻² are implanted into regions within the N-wells 40 and 41 at energy of about 130 keV, thereby the P-wells 50 and 51 are formed. The P-wells 50 and 51 can be formed at the same step to decrease the number of manufacturing steps or formed at different steps to make the P-wells 50 and 51 different in impurity concentration and depth.

The N-well 42 is formed in the region for forming the P-type FET. At this moment, by implanting phosphorous ions at a dosage of about 3×10¹³ cm⁻² into the region for forming the P-type FET at energy of about 500 keV, the N-well 42 is formed. Furthermore, phosphorus ions at a dosage of about 1.5×10¹³ cm⁻² are implanted into the N-well 42 at energy of about 290 keV, thereby setting a surface concentration of the N-well 42 to a predetermined concentration.

After forming the STI region, boron ions at a higher dosage than the dosage of the boron ions for forming the P-wells 50 and 51 are implanted into the SOI layer 30, thereby channel region of the FBC, channel region of the N-type FET and channel region of the P-type FET are formed, respectively. To decrease the number of manufacturing steps, the channel region of the FBC, the channel region of the N-type FET and the channel region of the P-type FET can be simultaneously formed at the same implantation step or formed at different implantation steps to make the channel region of the FBC, the channel region of the N-type FET and the channel region of the P-type FET different in impurity concentration.

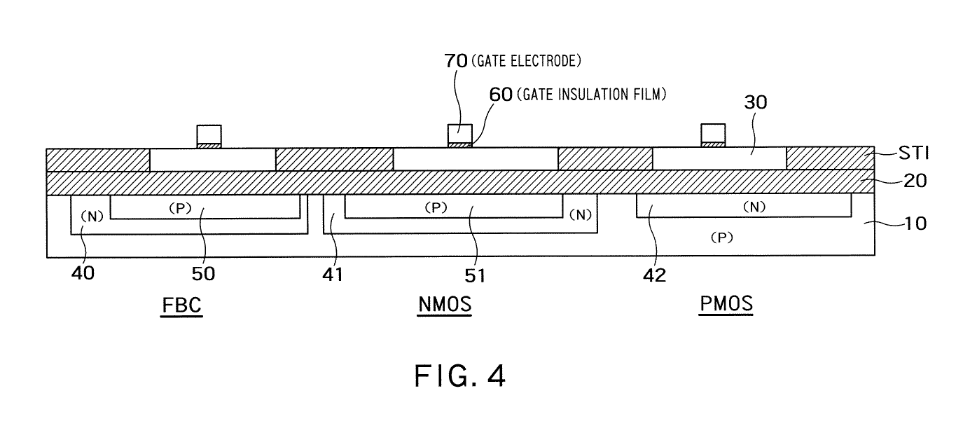

As shown in FIG. 4, the gate insulation film (gate oxide film) 60 is formed on the SOI layer 30. Next, boron silicon is deposited on the gate insulation film 60 by about 300 nm. The gate electrode 70 is thereby formed on the gate insulation film 60 by lithography and RIE (reactive-ion etching).

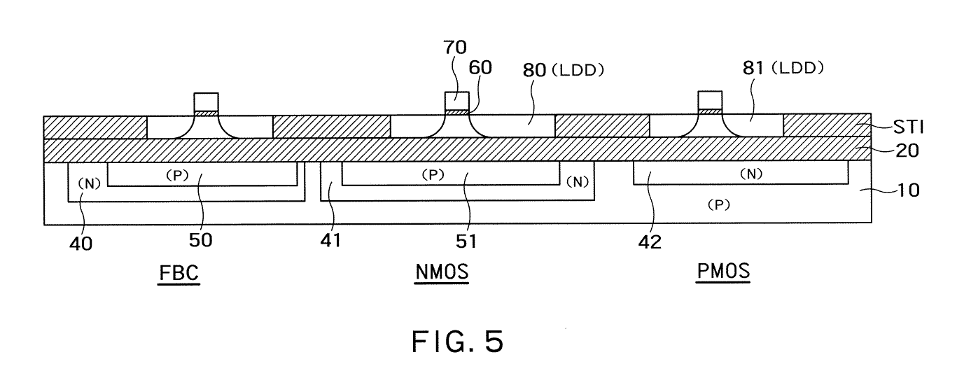

As shown in FIG. 5, using the gate electrode 70 as a mask, phosphorus or arsenic ions are implanted into the region for forming the FBC and the region for forming the N-type FET, thereby forming an N-type LDD (lightly diffused drain) region 80. Likewise, using the gate electrode 70 as a mask, boron ions are implanted into the region for forming the P-type FET, thereby forming a P-type LDD region 81.

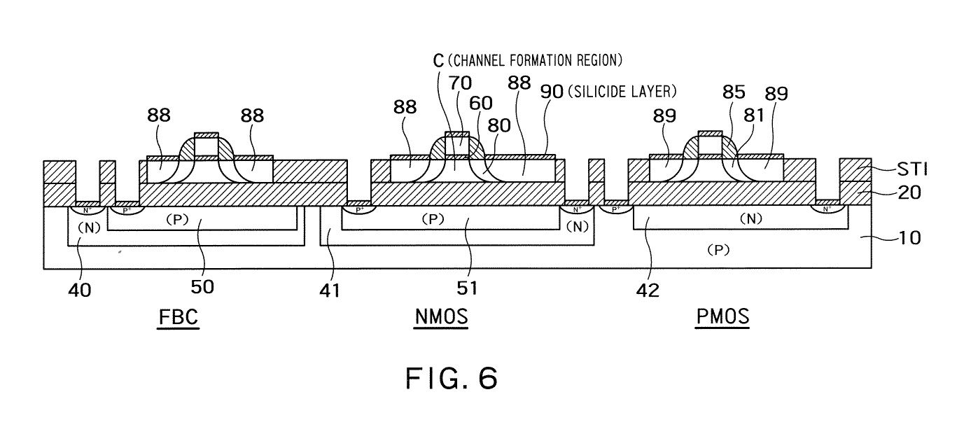

Next, a silicon oxide film is deposited by CVD (chemical vapor deposition) and anisotropically etched by the RIE. As a result, as shown in FIG. 6, a sidewall oxide film 85 is formed on a sidewall of the gate electrode 70.

To form the contact regions of the wells 40, 41, 42, 50, and 51, a part of the STI region is selectively removed until the support substrate 10 is exposed by the lithography and the RIE.

Using the gate electrode 70 and the sidewall oxide film 85 as a mask, an N-type diffused layer region 88 to serve as the source S and the drain D is formed in each of the region for forming the FBC and the region for forming the N-type FET. At the same time, an N-type diffused layer is formed in the contact regions of the wells 40 and 41. The N-type diffused regions 88 formed in the region for forming the FBC and that for forming the N-type FET can be formed at the same step or different steps.

Using the gate electrode 70 and the sidewall oxide film 85 as a mask, a P-type diffused region 89 to serve as the source S and the drain D is formed in the region for forming the P-type FET. At the same time, a P-type diffused layer is formed in the contact region of the well 42. Either at the same time or subsequently, a P-type diffused layer is formed in the contact regions of the wells 50 and 51.

An annealing treatment is performed at a high temperature of higher than 1000° C., thereby activating the impurities of the respective diffused layers. Thereafter, metal such as titanium is sputtered on the gate electrode 70 and the source and drain regions, and the silicon contained the gate electrode 70 is reacted with the titanium sputtered on the source and drain regions, thereby forming the titanium silicide layer 90.

Next, approximately 600 nm of a silicon oxide film 21 is deposited as an interlayer insulation film by LPCVD (low pressure CVD). Thereafter, contacts 95 are formed in the source layer S, the drain layer D, the gate electrode 70, and the wells 40, 41, 42, 50, and 51 (the contacts of the source region S, the drain region D, and the gate insulation film 70 are not shown in FIG. 1). Thereafter, by forming wirings and the like, the FBC memory device shown in FIG. 1 is completed.

1. A semiconductor memory device comprising:
a support substrate including a first conductivity type semiconductor;
an insulation film provided on the support substrate;
a semiconductor layer provided on the insulation film;
a first well of a second conductivity type provided in the support substrate;
second wells of the first conductivity type provided in the first well;
a third well of a second conductivity type provided in the support substrate;
a memory cell including a first source of the second conductivity type, a first drain of the second conductivity type and a body region formed between the first source and the first drain, the first source and the first drain being formed in the semiconductor layer located above one of the second wells, the body region being in an electrically floating state and accumulating or emitting charges for storing therein data;
a first logic circuit element including a second source of the second conductivity type, a second drain of the second conductivity type and a channel region of the first conductivity type formed between the second source and the second drain, the second source and the second drain being formed on the semiconductor layer above another one of the second wells; and
a second logic circuit element including a third source of the first conductivity type, a third drain of the first conductivity type and a channel region of the second conductivity type formed between the third source and the third drain, the third source and the third drain being formed on the semiconductor layer above the third well.

2. The semiconductor memory device according to claim 1, wherein the body region is the first conductivity type.

3. The semiconductor memory device according to claim 1, wherein the second well is used for a back bias gate.

4. The semiconductor memory device according to claim 2, wherein the second well is used for a back bias gate.

5. The semiconductor memory device according to claim 1, wherein the semiconductor memory device is a memory-logic integrated semiconductor memory device having the memory cell, the first logic circuit element, and the second logic circuit element provided on a same substrate.

6. The semiconductor memory device according to claim 2, wherein the semiconductor memory device is a memory-logic integrated semiconductor memory device having the memory cell, the first logic circuit element, and the second logic circuit element provided on a same substrate.

7. The semiconductor memory device according to claim 3, wherein the semiconductor memory device is a memory-logic integrated semiconductor memory device having the memory cell, the first logic circuit element, and the second logic circuit element provided on a same substrate.

8. The semiconductor memory device according to claim 1, wherein the first well is connected to a voltage source different from a voltage of the second well and from a voltage of the support substrate.

9. The semiconductor memory device according to claim 1, wherein the thickness of the insulation film is equal to or less than 50 nm.

10. The semiconductor memory device according to claim 1, wherein the memory cell is a floating body cell.

11. A method of manufacturing a semiconductor memory device comprising:
preparing a semiconductor substrate including a support substrate including a first conductivity type semiconductor, an insulation film provided on the support substrate, and a semiconductor layer provided on the insulation film;
forming a first well of a second conductivity type in the support substrate;
forming second wells of the first conductivity type in the first well;
forming a third well of the first conductivity type in the support substrate; and
forming a first source of the second conductivity type and a first drain of the second conductivity type in the semiconductor layer above one of the second well, a second source of the second conductivity type and a second drain of the second conductivity type in the semiconductor layer above another one of the second well, and a third source of the first conductivity type and a third drain of the first conductivity type in the semiconductor layer above the third well, wherein
the semiconductor layer between the first source and the first drain is used as a body region of the first conductivity type which is in an electrically floating state and accumulates or emits charges for storing therein data,
the semiconductor layer between the second source and the second drain is used as a channel region of the first conductivity type, and
the semiconductor layer between the third source and the third drain is used as a channel region of the second conductivity type.

12. The method of manufacturing a semiconductor memory device according to claim 11, wherein the second well is used for a back bias gate.

13. The semiconductor memory device according to claim 11, wherein the memory cell, the first logic circuit element, and the second logic circuit element are formed on a same die.

14. The semiconductor memory device according to claim 11, wherein the thickness of the insulation film is equal to or less than 50 nm.

15. The semiconductor memory device according to claim 11, wherein the memory cell is a floating body cell.
